(19) United States
(12) Patent Application Publication
(10) Pub. No.: US 2026/0324361 A1
(43) Pub. Date: Oct. 15, 2026

(54) RETAINER FOR A CHUCK TABLE

(71) Applicant: Skyworks Solutions, Inc., Irvine, CA (US)

(72) Inventors: Francisco Javier Leon Briones, Mexicali (MX); Aristeo Lanon Realica, Newbury Park, CA (US); Abnel Alcantar Morales, Mexicali (MX)

(21) Appl. No.: 19/464,350

(22) Filed: Jan. 29, 2026

Related U.S. Application Data
(60) Provisional application No. 63/751,734, filed on Jan. 30, 2025.

(51) Int. Cl. H10P 72/76

(52) U.S. Cl. CPC H10P 72/7606

(57) ABSTRACT

A retainer for retaining a wafer assembly on a chuck table supporting the wafer assembly during a cleaning process. The retainer comprises an attachment portion configured to attach the retainer to the chuck table; an abutment portion configured to abut a peripheral part of the wafer assembly, the abutment portion being slidably fixed to the attachment portion; and a biaser configured to bias the abutment portion towards the peripheral part of the wafer assembly such that the abutment portion pushes the peripheral part against a supporting surface of the chuck table so as to retain the wafer assembly on the chuck table.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to the field of semiconductor wafer processing technology, and more particularly, to systems and methods for cleaning a wafer.

### Description of the Related Technology

In certain wafer processing operations, such as cleaning a diced wafer, a wafer can be mounted on a chuck table. A chuck table is a disk shaped support configured to hold the wafer during the cleaning process.

The chuck table can form part of a wider cleaning tool, the cleaning tool being configured to clean the diced wafer by spraying a solvent across a surface of the wafer. The chuck table can be motor driven to facilitate this cleaning process.

### SUMMARY

According to one embodiment there is provided, a retainer for retaining a wafer assembly on a chuck table supporting the wafer assembly during a cleaning process, the retainer comprising: an attachment portion configured to attach the retainer to the chuck table; an abutment portion configured to abut a peripheral part of the wafer assembly, the abutment portion being slidably fixed to the attachment portion; and a biaser configured to bias the abutment portion towards the peripheral part of the wafer assembly such that the abutment portion pushes the peripheral part against a supporting surface of the chuck table so as to retain the wafer assembly on the chuck table.

In one example the biaser has a spring.

In one example the biaser further has a central core configured to engage the abutment portion.

In one example the retainer further comprises an adjustment element configured to adjust a pressure applied by the abutment portion to the peripheral part of the wafer assembly.

In one example the adjustment element has a screw mechanism configured to adjust the pressure applied by the abutment portion by increasing or decreasing a distance between the abutment portion in a rest position and the peripheral part of the wafer assembly.

In one example decreasing the distance between the abutment portion in the rest position and the peripheral part of the wafer assembly increases the pressure applied by the abutment portion.

In one example increasing the distance between the abutment portion in the rest position and the peripheral part of the wafer assembly decreases the pressure applied by the abutment portion.

In one example sliding the abutment portion relative to the attachment portion causes the biaser to exert a biasing force on the abutment portion in an opposite direction.

In one example the attachment portion has screws configured to attach the attachment portion to the chuck table.

According to another embodiment there is provided, A chuck table for supporting a wafer assembly during a cleaning process, the chuck table comprising: a supporting surface configured to support a wafer assembly; and a retainer configured to retain the wafer assembly on the chuck table, the retainer having: an attachment portion configured to attach the retainer to the chuck table; an abutment portion configured to abut a peripheral part of the wafer assembly, the abutment portion being slidably fixed to the attachment portion; and a biaser configured to bias the abutment portion towards the peripheral part of the wafer assembly such that the abutment portion pushes the peripheral part against the supporting surface of the chuck table so as to retain the wafer assembly on the chuck table.

In one example the attachment portion is attached to a peripheral portion of the chuck table.

In one example the chuck table further comprises a plurality of said retainers symmetrically disposed about a periphery of the chuck table.

According to another embodiment there is provided, A system for cleaning a wafer, the system comprising: a wafer assembly having a wafer; and a chuck table having a supporting surface supporting the wafer assembly and a retainer retaining the wafer assembly on the chuck table, the retainer including: an attachment portion configured to attach the retainer to the chuck table; an abutment portion configured to abut a peripheral part of the wafer assembly, the abutment portion being slidably fixed to the attachment portion; and a biaser configured to bias the abutment portion towards the peripheral part of the wafer assembly such that the abutment portion pushes the peripheral part against the supporting surface of the chuck table so as to retain the wafer assembly on the chuck table

In one example the wafer assembly further has a portion of tape, the wafer being disposed on the portion of tape.

In one example the wafer assembly further has a ring disposed about its periphery, the peripheral part of the wafer assembly being part of the ring.

In one example the supporting surface of the chuck table includes a raised portion with a profile that is complementary to the profile of the wafer assembly such that the abutment portion is configured to push the peripheral part of the wafer assembly against a complementary peripheral part of the raised portion.

According to another embodiment there is provided, A method for cleaning a wafer assembly, the method comprising: disposing a wafer assembly having a wafer on a supporting surface of a chuck table; abutting a peripheral part of the wafer assembly against an abutment portion of a retainer attached to the chuck table by way of an attachment portion so as to slide the abutment portion relative to the attachment portion such that the abutment portion is biased towards the peripheral part of the wafer assembly, thereby pushing the peripheral part of the wafer assembly against the supporting portion of the chuck table so as to retain the wafer assembly on the chuck table.

In one example the method further comprises initiating a cleaning cycle.

In one example the method further comprises adjusting a pressure applied by the abutment portion to the peripheral part of the wafer assembly

In one example adjusting the pressure applied by the abutment portion includes increasing or decreasing a distance between the abutment portion in a rest position and the peripheral part of the wafer assembly.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a known example sequence of wafer processing for forming through-wafer features such as vias;

FIGS. 2A to 2Y show examples of structures at various stages of the processing sequence of FIG. 1;

FIG. 3 is a schematic diagram of a known chuck table;

FIG. 4 illustrates a wafer that has been damaged during a known cleaning sequence;

FIG. 5 shows a wafer that has become dislodged from a chuck table during a known cleaning sequence;

FIGS. 6A to 6C are respectively schematic diagrams showing a top, side and bottom view of a retainer according to aspects of the present disclosure;

FIG. 7 is a schematic diagram of the retainer of FIGS. 6A to 6C according to aspects of the present disclosure;

FIG. 8 is a schematic diagram of the attachment portion of the retainer of FIG. 7 and its dimensions according to aspects of the present disclosure;

FIG. 9 is a schematic diagram of the abutment portion of the retainer of FIG. 7 and its dimensions according to aspects of the present disclosure;

FIG. 10 is a schematic diagram of part of the biaser of the retainer of FIG. 7 and its dimensions according to aspects of the present disclosure;

FIG. 11 is a schematic diagram of part of the biaser of the retainer of FIG. 7 and its dimensions according to aspects of the present disclosure;

FIG. 12 is a schematic diagram of the adjustment portion of the retainer of FIG. 7 and its dimensions according to aspects of the present disclosure;

FIGS. 13A and 13B show a chuck table having a retainer according to aspects of the present disclosure; and

FIG. 14 shows part of a wafer assembly retained on a chuck table using a retainer according to aspects of the present disclosure.

### DETAILED DESCRIPTION

Aspects and embodiments described herein are directed to a retainer for retaining a wafer assembly on a chuck table, preventing the wafer assembly from becoming dislodged during a cleaning process.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

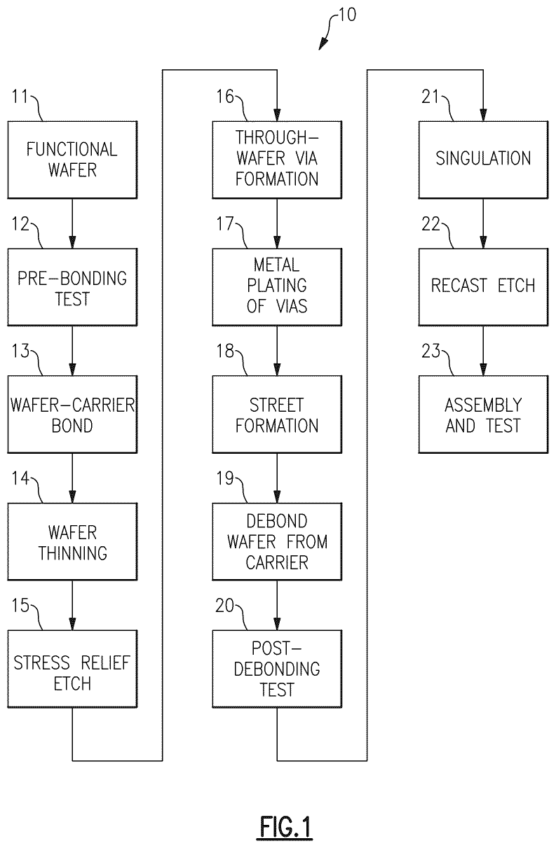

FIG. 1 shows an example of a process 10 where a functional wafer is further processed to form through wafer-features such as vias and back-side metal layers. As further shown in FIG. 1, the example process 10 can include bonding of a wafer to a carrier for support and/or to facilitate handling during the various steps of the process, and debonding of the wafer from the carrier upon completion of such steps. FIG. 1 further shows that such a wafer separated from the carrier can be further processed so as to yield a number of dies.

In the description herein, various examples are described in the context of GaAs substrate wafers. It will be understood, however, that some or all of the features of the present disclosure can be implemented in processing of other types of semiconductor wafers. Further, some of the features can also be applied to situations involving non-semiconductor wafers.

In the description herein, various examples are described in the context of back-side processing of wafers. It will be understood, however, that some or all of the features of the present disclosure can be implemented in front-side processing of wafers.

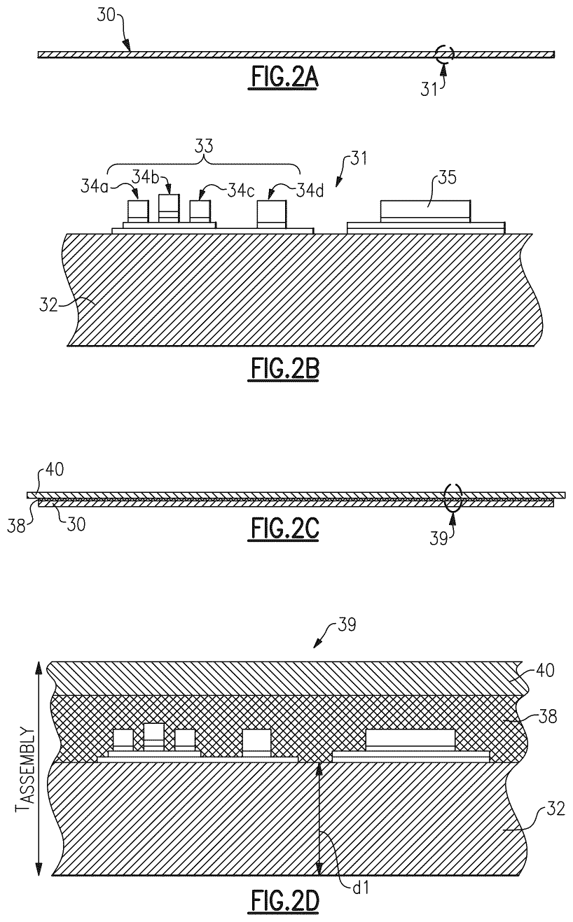

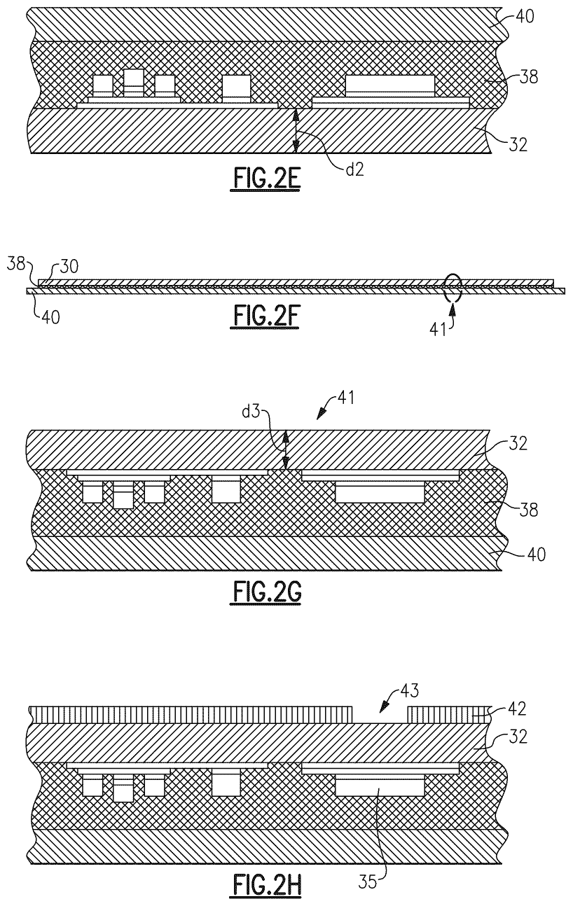

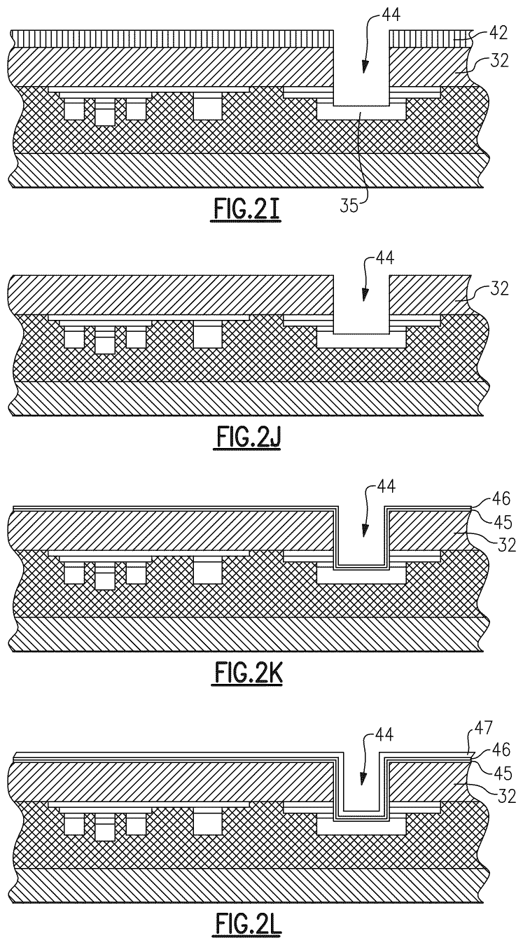

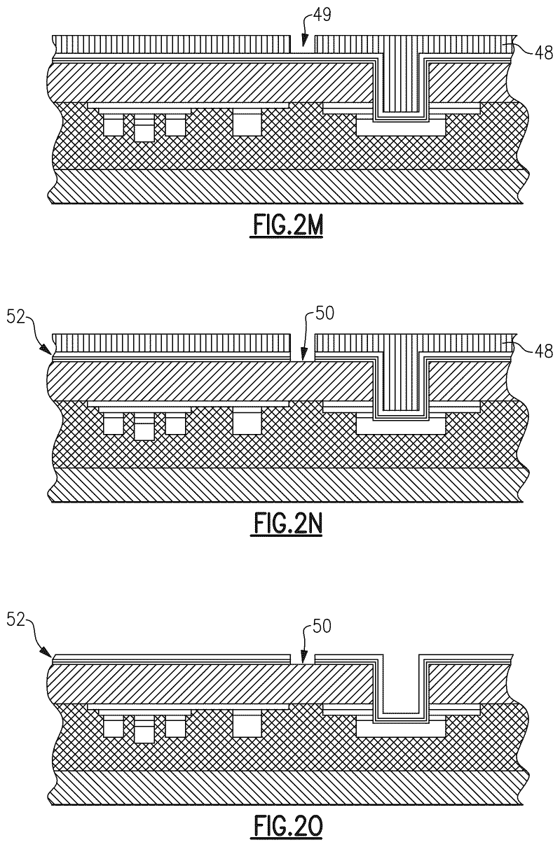

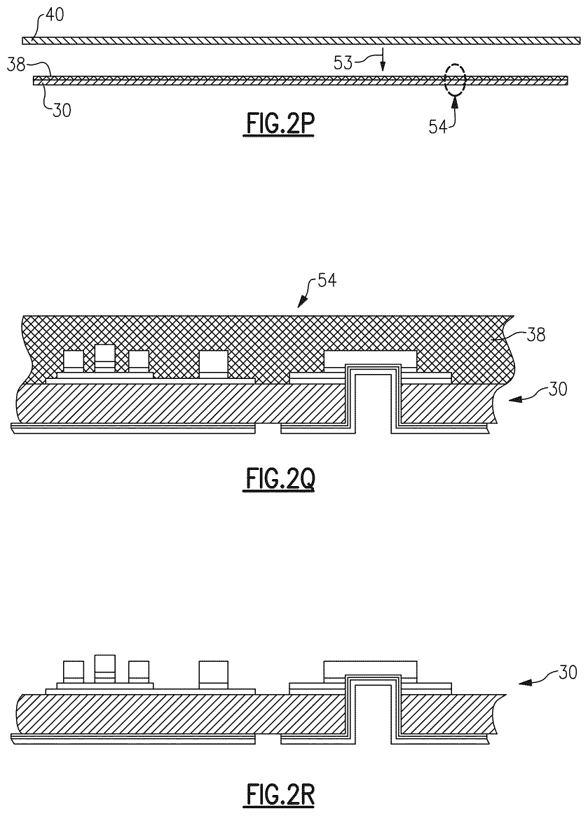

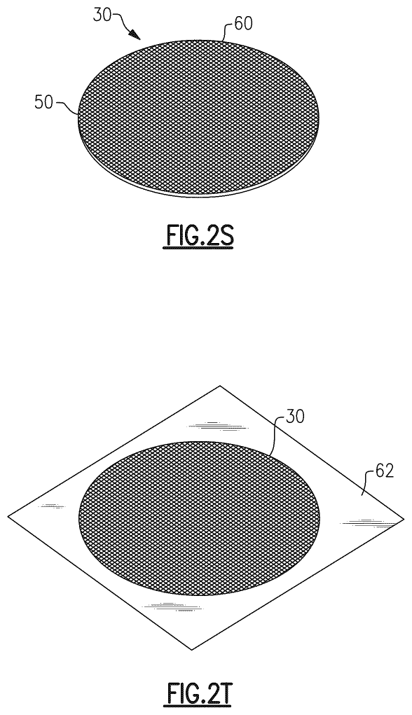

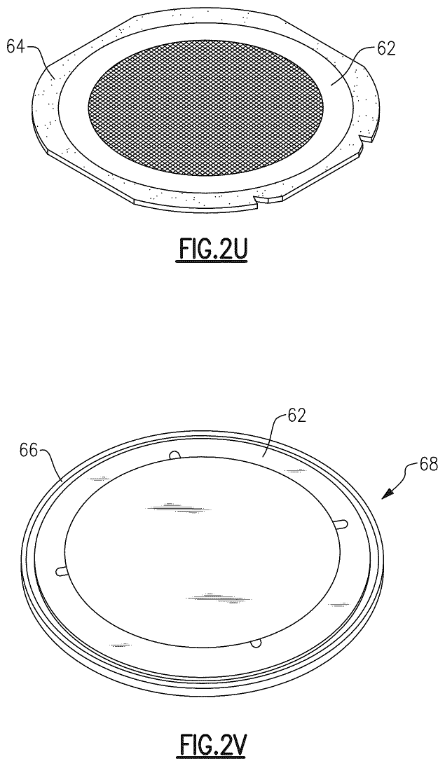

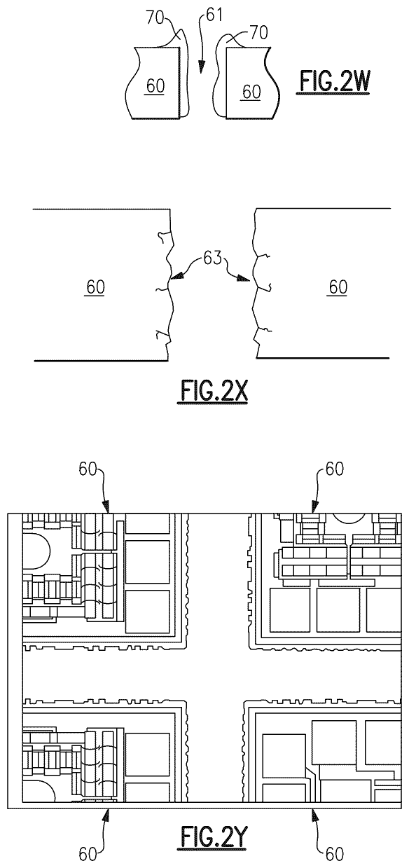

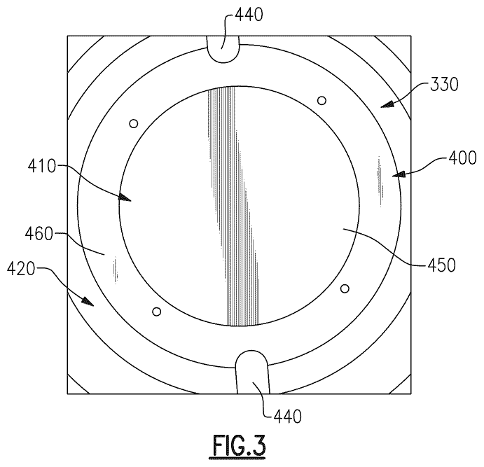

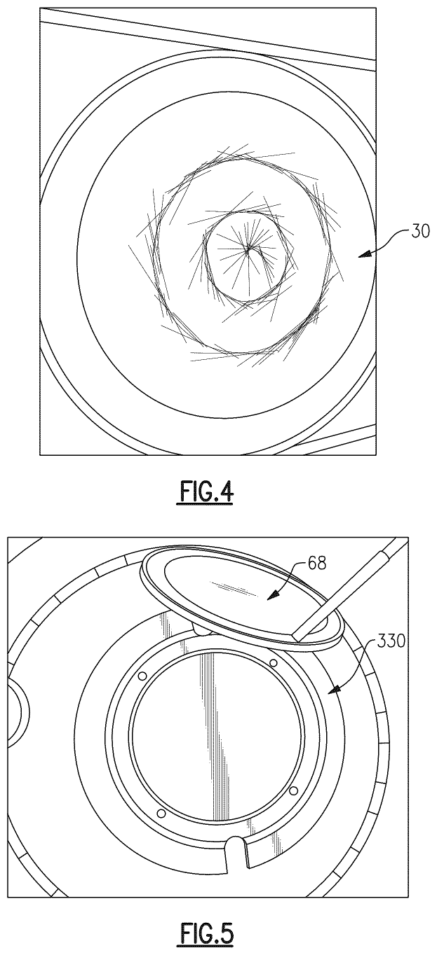

In the process 10 of FIG. 1, a functional wafer can be provided (block 11). FIG. 2A depicts a side view of such a wafer 30 having first and second sides. The first side can be a front side and the second side a back side.

FIG. 2B depicts an enlarged view of a portion 31 of the wafer 30. The wafer 30 can include a substrate layer 32 (e.g. a GaAs substrate layer). The wafer 30 can further include a number of features formed on or in its front side. In the example shown, a transistor 33 and a metal pad 35 are depicted as being formed on the front side. The example transistor 33 is depicted as having an emitter 34b, bases 34a, 34c, and a collector 34d. Although not shown, the circuitry can also include formed passive components such as inductors, capacitors, and source, gate and drain for incorporation of planar field effect transistors (FETs) with heterojunction bipolar transistors (HBTs). Such structures can be formed by various processes performed on epitaxial layers that have been deposited on the substrate layer.

Referring to the process 10 of FIG. 1, the functional wafer of block 11 can be tested (block 12) in a number of ways prior to bonding. Such a pre-bonding test can include, for example, DC and RF tests associated with process control parameters.

Upon such testing, the wafer can be bonded to a carrier (block 13). In certain implementations, such a bonding can be achieved with the carrier above the wafer. Thus, FIG. 2C shows an example assembly of the wafer 30 and a carrier 40 (above the wafer) that can result from the bonding step 13. In certain implementations, the wafer and carrier can be bonded using temporary mounting adhesives such as wax or commercially available Crystalbond™. In FIG. 2C, such an adhesive is depicted as an adhesive layer 38.

An enlarged portion 39 of the bonded assembly in FIG. 2C is depicted in FIG. 2D. The bonded assembly can include the GaAs substrate layer 32 on which are a number of devices such as the transistor 33 and metal pad 35 as described in reference to FIG. 2B. The wafer 30 having such substrate 32 and devices (e.g., 33, 35) is depicted as being bonded to the carrier plate 40 via the adhesive layer 38.

As shown in FIG. 2D, the substrate layer 32 at this stage has a thickness of d1, and the carrier plate 40 has a generally fixed thickness. Thus, the overall thickness (T_{assembly}) of the bonded assembly can be determined by the amount of adhesive in the layer 38.

In a number of processing situations, it is preferable to provide a sufficient amount of adhesive to cover the tallest feature(s) so as to yield a more uniform adhesion between the wafer and the carrier plate, and also so that such a tall feature does not directly engage the carrier plate. Thus, in the example shown in FIG. 2D, the emitter feature (34b in FIG. 2B) is the tallest among the example features; and the adhesive layer 38 is sufficiently thick to cover such a feature and provide a relatively uninterrupted adhesion between the wafer 30 and the carrier plate 40.

Referring to the process 10 of FIG. 1, the wafer-now mounted to the carrier plate-can be thinned so as to yield a desired substrate thickness in blocks 14 and 15. In block 14, the back side of the substrate 32 can be ground away (e.g. via a two-step grind with coarse and fine diamond-embedded grinding wheels) so as to yield an intermediate thickness substrate (with thickness d2 as shown in FIG. 2E) with a relatively rough surface. In certain implementations, such a grinding process can be performed with the bottom surface of the substrate facing downward.

In block 15, the relatively rough surface can be removed so as to yield a smoother back surface for the substrate 32. In certain implementations, such removal of the rough substrate surface can be achieved by an O₂ plasma ash process, followed by a wet etch process utilizing acid or base chemistry. Such an acid or base chemistry can include HCl, H₂SO₄, HNO₃ H₃PO₄, H₃COOH, NH₄OH, H₂O₂, etc., mixed with H₂O₂ and/or H₂O. Such an etching process can provide relief from possible stress on the wafer due to the rough ground surface.

In certain implementations, the foregoing plasma ash and wet etch process can be performed with the back side of the substrate 32 facing upward. Accordingly, the bonded assembly in FIG. 2F depicts the wafer 30 above the carrier plate 40. FIG. 2G shows the substrate layer with a thinned and smoothed surface, and a corresponding thickness of d3.

By way of an example, the pre-grinding thickness (d1 in FIG. 2D) of a 150 mm (also referred to as “6-inch”) GaAs substrate can be approximately 675 μm. The thickness d2 (FIG. 2E) resulting from the grinding process can be in a range of approximately 102 μm to 120 μm. The ash and etching processes can remove approximately 2 μm to 20 μm of the rough surface so as to yield a thickness of approximately 100 μm (d3 in FIG. 2G). Other thicknesses are possible.

In certain situations, a desired thickness of the back-side-surface-smoothed substrate layer can be an important design parameter. Accordingly, it is desirable to be able to monitor the thinning (block 14) and stress relief (block 15) processes. Since it can be difficult to measure the substrate layer while the wafer is bonded to the carrier plate and being worked on, the thickness of the bonded assembly can be measured so as to allow extrapolation of the substrate layer thickness. Such a measurement can be achieved by, for example, a gas (e.g., air) back pressure measurement system that allows detection of surfaces (e.g., back side of the substrate and the “front” surface of the carrier plate) without contact.

As described in reference to FIG. 2D, the thickness (T_{assembly}) of the bonded assembly can be measured; and the thicknesses of the carrier plate 40 and the un-thinned substrate 32 can have known values. Thus, subsequent thinning of the bonded assembly can be attributed to the thinning of the substrate 32; and the thickness of the substrate 32 can be estimated.

Referring to the process 10 of FIG. 1, the thinned and stress-relieved wafer can undergo a through-wafer via formation process (block 16). FIGS. 2H to 2J show different stages during the formation of a via 44. Such a via is described herein as being formed from the back side of the substrate 32 and extending through the substrate 32 so as to end at the example metal pad 35. It will be understood that one or more features described herein can also be implemented for other deep features that may not necessarily extend all the way through the substrate. Moreover, other features (whether or not they extend through the wafer) can be formed for purposes other than providing a pathway to a metal feature on the front side.

To form an etch resist layer 42 that defines an etching opening 43 (FIG. 2H), photolithography can be utilized. Coating of a resist material on the back surface of the substrate, exposure of a mask pattern, and developing of the exposed resist coat can be achieved in known manners. In the example configuration of FIG. 2H, the resist layer 42 can have a thickness in the range of about 15 μm to 20 μm.

To form a through-wafer via 44 (FIG. 2I) from the back surface of the substrate to the metal pad 35, techniques such as dry inductively coupled plasma (ICP) etching (with chemistry such as BCl₃/Cl₂) can be utilized. In various implementations, a desired shaped via can be an important design parameter for facilitating proper metal coverage therein subsequent processes.

FIG. 2J shows the formed via 44, with the resist layer 42 removed. To remove the resist layer, photoresist strip solvents such as NMP (N-methyl-2-pyrrolidone) and EKC can be applied using, for example, a batch spray tool. In various implementations, proper removal of the resist material 42 from the substrate surface can be an important consideration for subsequent metal adhesion. To remove residue of the resist material that may remain after the solvent strip process, a plasma ash (e.g. O₂) process can be applied to the back side of the wafer.

Referring to the process 10 of FIG. 1, a metal layer can be formed on the back surface of the substrate 32 in block 17. FIGS. 2K and 2L show examples of adhesion/seed layers and a thicker metal layer.

FIG. 2K shows that in certain implementations, an adhesion layer 45 such as a nickel vanadium (NiV) layer can be formed on surfaces of the substrate's back side and the via 44 by, for example, sputtering. Preferably, the surfaces are cleaned (e.g. with HCl) prior to the application of NiV. FIG. 2K also shows that a seed layer 46 such as a thin gold layer can be formed on the adhesion layer 45 by, for example, sputtering. Such a seed layer facilitates formation of a thick metal layer 47 such as a thick gold layer shown in FIG. 2L. In certain implementations, the thick gold layer can be formed by a plating technique.

In certain implementations, the gold plating process can be performed after a pre-plating cleaning process (e.g. O₂ plasma ash and HCl cleaning). The plating can be performed to form a gold layer of about 3 μm to 6 μm to facilitate the foregoing electrical connectivity and heat transfer functionalities. The plated surface can undergo a post-plating cleaning process (e.g. O₂ plasma ash).

The metal layer formed in the foregoing manner forms a back side metal plane that is electrically connected to the metal pad 35 on the front side. Such a connection can provide a robust electrical reference (e.g. ground potential) for the metal pad 35. Such a connection can also provide an efficient pathway for conduction of heat between the back side metal plane and the metal pad 35.

Thus, one can see that the integrity of the metal layer in the via 44 and how it is connected to the metal pad 35 and the back side metal plane can be important factors for the performance of various devices on the wafer. Accordingly, it is desirable to have the metal layer formation be implemented in an effective manner. More particularly, it is desirable to provide an effective metal layer formation in features such as vias that may be less accessible.

Referring to the process 10 of FIG. 1, the wafer having a metal layer formed on its back side can undergo a street formation process (block 18). FIGS. 2M to 2O show different stages during the formation of a street 50. Such a street is described herein as being formed from the back side of the wafer and extending through the metal layer 52 to facilitate subsequent singulation of dies. It will be understood that one or more features described herein can also be implemented for other street-like features on or near the back surface of the wafer. Moreover, other street-like features can be formed for purposes other than to facilitate the singulation process.

To form an etch resist layer 48 that defines an etching opening 49 (FIG. 2M), photolithography can be utilized. Coating of a resist material on the back surface of the substrate, exposure of a mask pattern, and developing of the exposed resist coat can be achieved in known manners.

To form a street 50 (FIG. 2N) through the metal layer 52, techniques such as wet etching (with chemistry such as potassium iodide) can be utilized. A pre-etching cleaning process (e.g. O₂ plasma ash) can be performed prior to the etching process. In various implementations, the thickness of the resist 48 and how such a resist is applied to the back side of the wafer can be important considerations to prevent certain undesirable effects, such as via rings and undesired etching of via rim during the etch process.

FIG. 2O shows the formed street 50, with the resist layer 48 removed. To remove the resist layer 48, photoresist strip solvents such as NMP (N-methyl-2-pyrrolidone) can be applied using, for example, a batch spray tool. To remove residue of the resist material that may remain after the solvent strip process, a plasma ash (e.g. O₂) process can be applied to the back side of the wafer.

In the example back-side wafer process described in reference to FIGS. 1 and 2 the street 50 formation and removal of the resist 48 yields a wafer that no longer needs to be mounted to a carrier plate. Thus, referring to the process 10 of FIG. 1, the wafer is debonded or separated from the carrier plate in block 19. FIGS. 2P to 2R show different stages of the separation and cleaning of the wafer 30.

In certain implementations, separation of the wafer 30 from the carrier plate 40 can be performed with the wafer 30 below the carrier plate 40 (FIG. 2P). To separate the wafer 30 from the carrier plate 40, the adhesive layer 38 can be heated to reduce the bonding property of the adhesive. For the example Crystalbond™ adhesive, an elevated temperature to a range of about 130° C. to 170° C. can melt the adhesive to facilitate an easier separation of the wafer 30 from the carrier plate 40. Some form of mechanical force can be applied to the wafer 30, the carrier plate 40, or some combination thereof, to achieve such separation (arrow 53 in FIG. 2P). In various implementations, achieving such a separation of the wafer with reduced likelihood of scratches and cracks on the wafer can be an important process parameter for facilitating a high yield of good dies.

In FIGS. 2P and 2Q, the adhesive layer 38 is depicted as remaining with the wafer 30 instead of the carrier plate 40. It will be understood that some adhesive may remain with the carrier plate 40.

FIG. 2R shows the adhesive 38 removed from the front side of the wafer 30. The adhesive can be removed by a cleaning solution (e.g. acetone), and remaining residues can be further removed by, for example, a plasma ash (e.g. O₂ process).

Referring to the process 10 of FIG. 1, the debonded wafer of block 19 can be tested (block 20) in a number of ways prior to singulation. Such a post-debonding test can include, for example, resistance of the metal interconnect formed on the through-wafer via using process control parameters on the front side of the wafer. Other tests can address quality control associated with various processes, such as quality of the through-wafer via etch, seed layer deposition, and gold-plating.

FIG. 2S illustrates a GaAs wafer 30 with a plurality of individual integrated circuits 60 (also referred to herein as dies). As shown in FIG. 2S, streets 50 have been formed in the regions between each integrated circuit 60 on the wafer 30.

Following street formation, the wafer 30 is placed onto cutting tape 62, with the back side of the GaAs wafer 30 adhering to the cutting tape 62 in the manner shown in FIG. 2T. The cutting tape is further mounted to a dicing frame 64 to hold the wafer 30 during the cutting process, as shown in FIG. 2U. Next, the integrated circuit dies are singulated or diced by cutting through the GaAS wafer 30 along the pre-formed streets 50. A scribe may be applied to the streets in order to mechanically singulate the integrated circuit dies. Alternatively, a laser may be used to burn through the streets 50. Mechanical scribing is inexpensive, but is typically less accurate than laser singulation, and may cause damage to the die. Laser singulation is more accurate and reduces damage, but at increased expense.

Referring to FIG. 2V, once the integrated circuit dies have been singulated, the cutting tape 62 is stretched apart. This stretching ensures that the dies 60 have been singulated, as it results in widening the separation between each of the dies. The cutting tape may be stretched until the tape 62 is visible between each of the dies. FIG. 2V shows a wafer that has undergone the expansion process. During the stretching process, the wafer and tape are fitted to a grip ring 66 which retains the wafer 30 and tape 62 in their expanded state. The grip ring 66 is positioned between the periphery of the wafer 30 and the inner perimeter of the dicing frame 64. Once stretched, the dicing frame 64 and the excess tape 62 surrounding the grip ring 66 is removed. What remains is referred to as a wafer assembly 68 herein, comprising a wafer 30, cutting tape 62 and ring 66. The wafer assembly 68 has two opposing faces. The wafer side is defined as the side on which the wafer 30 is disposed. The remaining face on which the wafer 30 is not disposed is referred to herein as the tape side.

Referring still to FIG. 2V, the wafer side of the wafer assembly 68 comprises a generally disk-shaped wafer 30 disposed on cutting tape 62. The cutting tape 62 is also disk shaped, with a larger radial extent than the wafer 30. The wafer 30 is generally positioned in the center of the cutting tape 62, such that a peripheral ring-shaped area of the cutting tape 62 is uncovered by the wafer 30 on the wafer side of the wafer assembly 68. In other words, the wafer assembly 68 comprises a wafer 30 disposed on a portion of tape 62, the portion of tape 62 having a first diameter that is larger than a second diameter of the wafer 30, and the wafer assembly 68 being configured such that on a first face of the wafer assembly 68 a peripheral area of the tape 62 is uncovered by the wafer 30. The ring 66 is disposed around the periphery of the cutting tape 62 such that the ring 66 defines the thickest section of the wafer assembly 68.

In the context of laser cutting, FIG. 2W shows an effect on the edges of adjacent dies 60 cut by a laser. As the laser makes the cut, a rough edge feature 70 (commonly referred to as a recast) typically forms. Presence of such a recast can increase the likelihood of formation of a crack therein and propagating into the functional part of the corresponding die.

Thus, referring to the process in FIG. 1, a recast etch proves using acid and/or base chemistry (e.g. similar to the examples described in reference to block 15) can be performed in block 22. Such etching of the recast feature and defects formed by the recast, increases the die strength and reduces the likelihood of die crack failures (FIG. 2X).

Referring to the process of FIG. 1, the recast etched dies (FIG. 2Y) can be further inspected and subsequently be packaged.

After singulation, remnants or debris from the cutting process may remain on the wafer. The wafer may therefore be cleaned after singulation to remove such residue. This cleaning process may be carried out while the wafer remains attached to the cutting tape and ring. Known cleaning tools (also referred to herein as washers) clean by cleaning fluid (e.g. an alcohol) sprayed through a spray head on a swivel arm, for example. The swivel arm allows the solvent spray to sweep across the wafer.

A chuck table is provided for holding the wafer assembly during the foregoing cleaning process. A chuck table is a disk shaped support configured to hold the wafer during the cleaning process. Chuck tables are well known in the field of cleaning tools for semiconductor wafers. During cleaning, the chuck table is rotated by a motor. When supporting a wafer assembly, the rotation of the chuck table leads to rotation of the wafer assembly. The combination of the rotating chuck table and swivel arm, for example, allows the cleaning fluid to be applied to the entirety of the wafer. The skilled person will understand that a chuck table can be used with other washer types. The chuck table/motor reaches speeds of around 2000 rpm at certain points of the cleaning process. Due to the high rotation speeds reached at some points during the cleaning cycle, there is a known problem of wafer assemblies being thrown off the chuck table and subsequently damaged.

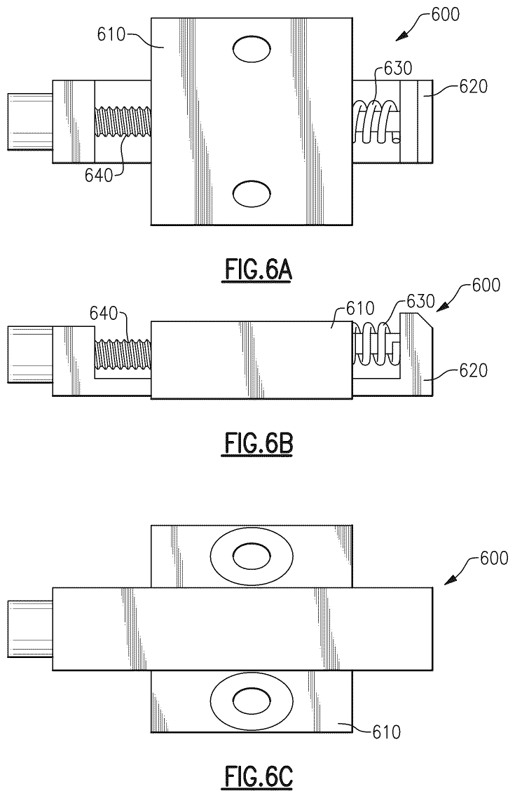

FIG. 3 shows an example of a known chuck table 330 for supporting and holding a wafer assembly during a cleaning process. The chuck table has a generally circular cross section (i.e. is generally disk shaped). Generally disk-shaped refers to the fact that the peripheral edge of the chuck table includes features such as indentations 440 to enable easy removal of a wafer assembly from the chuck table. Said features interrupt the perimeter of the chuck table. In this way, the chuck table is not perfectly disk shaped. Such a circular cross section is complementary to the disk-shape of a wafer/wafer assembly. The chuck table comprises a supporting surface 400. The supporting surface is configured to support/hold a wafer assembly during the cleaning process. The surface comprises a central portion 410 and a peripheral portion 420. The central portion is raised relative to the peripheral portion. The central portion also has a generally circular cross section. The peripheral portion surrounds the central portion. The peripheral portion has a generally ring shaped cross section. The inner perimeter of the peripheral portion is complementary to the shape of the outer perimeter of the central portion. In other words, the surface comprises a central raised portion surrounded by a sunken peripheral portion. As discussed above with reference to FIG. 2V, the ring of the wafer assembly defines the thickest portion of the wafer assembly. The sunken portion is therefore configured to accommodate the extra thickness of the wafer assembly at the location of the ring. In this way, when a wafer assembly is disposed on the chuck table such that the ring rests on the sunken portion, lateral movement of the wafer assembly is prevented. In other words, the geometry of the sunken peripheral portion is complementary to a geometry of the ring of the wafer assembly. The chuck table further comprises holes. The holes are configured to facilitate mounting the chuck table to a washer such that the chuck table can be driven by a motor of the cleaning tool to rotate. These mounting holes are therefore configured to receive couplings that are suitable for securing the chuck table to the cleaning tool. Suitable couplings are screws, for example.

The central portion of the chuck table further comprises a central disk shaped section 450 and a ring shaped section. The ring shaped section extends around the periphery of the central disk shaped section 460. The disk shaped section and ring shaped section are both made from differing materials. The disk shaped section comprises a porous material. The ring shaped section comprises engineering plastics. Both the mounting holes and handling indentations are located in the ring shaped section of the chuck table.

The central porous section of the chuck table is configured to be in communication with a vacuum source (not shown) of the cleaning tool. As previously discussed, due to the high rotation speeds reached at some points during the cleaning cycle, there is a problem with wafer assemblies being thrown off the chuck table and subsequently damaged. This is particularly true of drying sequences, during which high rotation rates are experienced. The central porous section is, therefore, configured to deliver a suction force on the wafer assembly such as to hold the wafer assembly and reduce the likelihood of the wafer assembly being damaged and subsequently rejected. A sensor detects whether the vacuum pressure exceeds a threshold. If yes, the system assumes the vacuum is holding the wafer assembly in place, and the cleaning cycle is initiated. However, the vacuum source can often become clogged. The sensor senses that the vacuum pressure exceeds the threshold, and attributes this to the incorrect assumption that the wafer assembly is being held in place. In this situation, the cleaning cycle is initiated, leading to assemblies becoming dislodged. FIG. 4 shows examples of such a damaged wafer 30. FIG. 5 shows an example of a wafer assembly 68 that has become dislodged from the chuck table.

According to some aspects of the present disclosure, a retainer for retaining a wafer assembly on a chuck table during a cleaning process is provided.

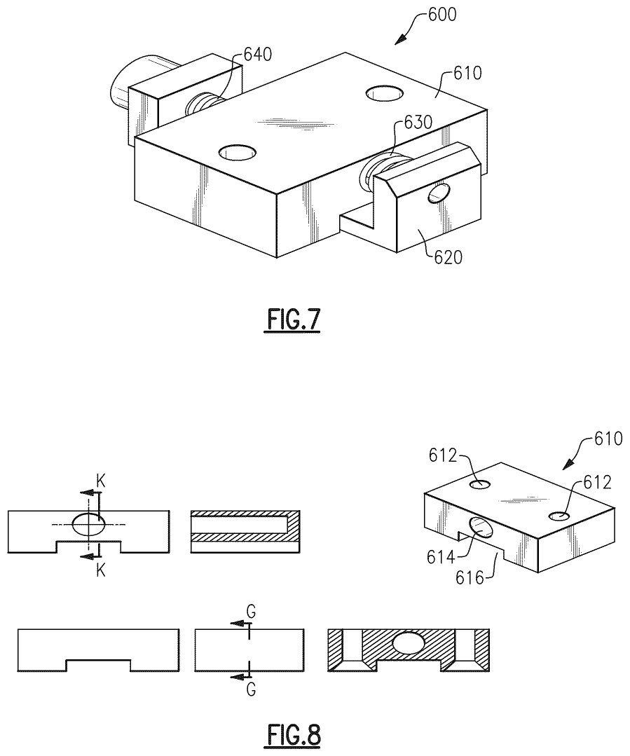

An embodiment of a retainer 600 is shown in FIGS. 6A to 6C and 7. The retainer comprises an attachment portion 610. The attachment portion is configured to enable attachment of the retainer to the chuck table. The retainer further comprises an abutment portion 620. The abutment portion is configured to abut a peripheral part of the wafer assembly. The abutment portion is slidably fixed to the attachment portion. The retainer further comprises a biaser 630. The biaser is configured to bias the abutment portion towards the peripheral part of the wafer assembly. In this way, as is explained in more detail below, when in use the abutment portion pushes the peripheral part of the wafer assembly against the supporting surface of the chuck table. This, in turn, retains or holds the wafer assembly on the chuck table. In this example, the retainer further comprises an adjustment element 640. The adjustment element is configured to adjust the pressure applied by the abutment portion to the peripheral part of the wafer assembly.

The example attachment portion 610 and its configuration is illustrated in more detail in FIG. 8. The attachment portion comprises top down through holes 612. These through holes are configured to receive screws for fixing or attaching the retainer to a chuck table. In this example, there are two such top down through holes. The skilled person will understand that other means would be suitable for fixing the retainer to a chuck table. The attachment portion further comprises a further through hole 614. The further through hole is a lateral through hole. In other words, it extends through the attachment portion in a direction perpendicular to the top down through hole. The through hole has a portion configured to receive the biasing means, as is described in more detail below. The dimensions of said portion of the through hole are such that they are complementary to the biasing means. A second portion of the through hole is configured to receive the adjustment element, described in more detail below. The dimensions of said portion are such that they are complementary to the adjustment element. In this example, where the adjustment element is a screw described in more detail below, said portion of the through hole is threaded to receive the screw. In this way the adjustment element extends both through the abutment portion and the attachment portion. In this example, the attachment portion comprises one such through hole. However, the skilled person will understand that, in other examples, the attachment portion will be adapted to receive the specific biasing means and adjustment elements in use. The attachment means is further configured to receive the abutment portion. More specifically, the attachment means is configured to receive the abutment portion such that the abutment portion is slidably fixed to the attachment portion. In other words, the abutment portion is fixed to the attachment portion in such a way that lateral movement of the abutment portion relative to the attachment portion is permitted in one direction. In this example, the profile of the attachment portion is such that, when fixed to a chuck table, a space with a width and height complimentary to the profile of the abutment portion exists between the chuck table and the attachment portion. In other words, the attachment portion comprises a recessed area 616 with a width and height that corresponds to the dimensions of the abutment portion. The recessed area extends through the length of the attachment portion. This recessed area receives the abutment portion receives the abutment portion. However, the skilled person will understand that other configurations are possible.

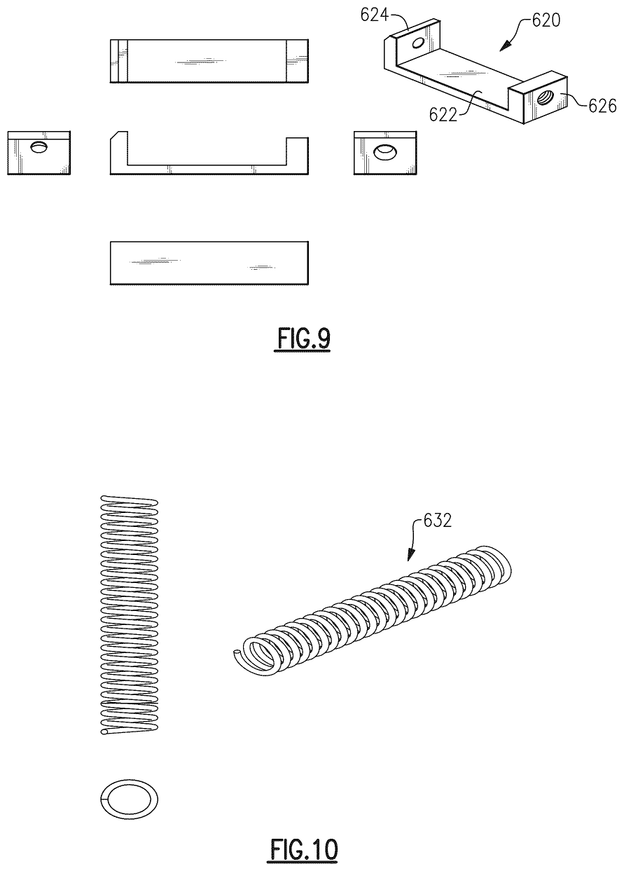

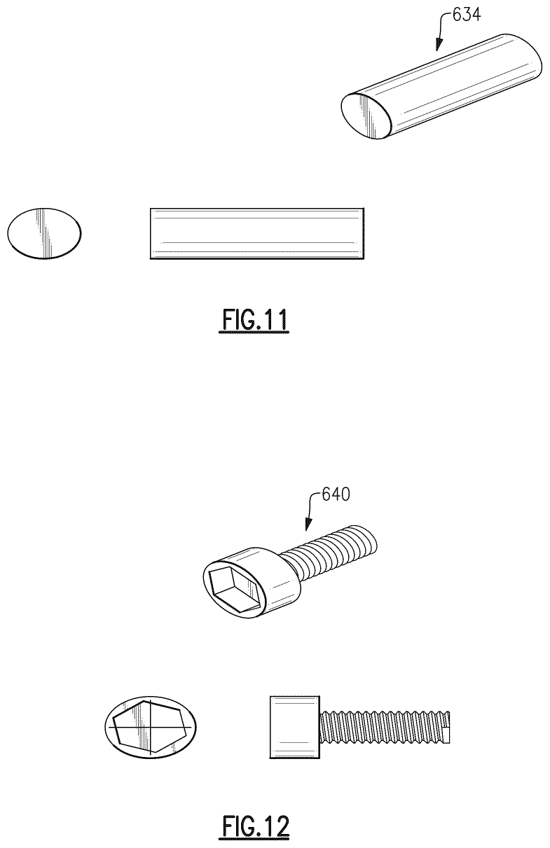

The example abutment portion 620 and its dimensions are illustrated in FIG. 9. The abutment portion comprises a substantially flat body 622. The substantially flat body is configured to be positioned in the recessed area of the attachment portion. The height and width of the substantially flat body is complementary to that of the recessed area. The length of the substantially flat body exceeds that of the attachment portion. The abutment portion further comprises a first protrusion 624. The abutment portion further comprises a second protrusion 626. The first protrusion extends from a first end of the flat body. This first end, in use, is configured to abut a peripheral part of the wafer assembly. In other words, it is closer to the center of the chuck table than a second end of the abutment portion. The first protrusion comprises a through hole. The through hole is configured to receive the biasing means, explained in more detail below. The first through hole, therefore, is configured to be in line with through hole 614 of the attachment portion. In this way, the biasing means can extend both through the attachment portion and the through hole of the abutment portion. The second protrusion extends from the second end of the flat body. The second protrusion comprises a through hole. The through hole is configured to receive the adjustment element of the retainer. The dimensions of the through hole, therefore, are complementary to that of the adjustment element. In this example, where the adjustment element is a screw as described in more detail below, the through hole is threaded so as to receive the screw. The through hole is in line with through hole 614 of the attachment portion. In this way, the adjustment element extends through the attachment portion and the abutment element. When positioned in the recessed area of the attachment portion, the flat body and the attachment portion form a substantially flat surface. The first and second protrusions extend beyond the height of the recessed section of the attachment portion. In this way, the abutment portion is slidable relative to the attachment portion, with the first and second protrusions acting as barriers defining the extent to which the abutment portion is slidable.

The example biasing means and its configuration is illustrated in more detail in FIGS. 10 to 11. In this example, the biaser is a spring mechanism. In other words, the biasing means comprises a spring 632. The biasing means further comprises a central core 634. The central core is configured to extend through the spring. The central core is configured to engage the abutment portion, explained in more detail below. In this way, in use, when the abutment portion slides relative to the attachment portion in a direction that compresses the spring, the restoring force of the spring pushes the abutment portion in the direction opposite to said compression. In other words, sliding the abutment portion relative to the attachment portion causes the biaser to exert a biasing force on the abutment portion in an opposite direction. In yet other words, in use, the restoring force of the spring pushes the abutment portion against a peripheral part of the wafer assembly. This, in turn, holds or secures said peripheral part of the wafer assembly to a supporting surface of the chuck table. The central core acts as a reinforcing element for the spring. In this way, the central core keeps the spring in place. In other words, the tension in the spring keeps the wafer assembly in place.

The example adjustment portion and its dimensions are illustrated in FIG. 12. The adjustment element 640 is configured to adjust a pressure applied by the abutment portion to the peripheral part of the wafer assembly. More specifically, the adjustment element is configured to adjust a pressure applied by the abutment portion to the peripheral part of the wafer assembly by, in use, adjusting the positioning of the abutment portion to be closer to the peripheral part of the wafer assembly. This, in turn, increases the compression in the spring of the biasing element. This, in turn, increases the restoring force and, therefore, the pressure applied by the abutment portion on the peripheral part of the wafer assembly. In this example, the adjustment element is a screw. The screw is configured to extend through both the abutment portion and the attachment portion, as explained above. This is by way of the fact that through holes of the attachment portion and abutment portion are in line, as is explained in more detail above. The screw head is positioned on the outer side of the second protrusion. In this way, screwing the adjustment element further into the attachment portion pushes the second protrusion of the abutment element closer to the attachment portion, sliding the first protrusion of the abutment element closer to the center of the chuck table in use. In this way, the restoring force of the spring of the biasing element is increased when pushing against a wafer assembly. This, thereby, increases the pressure applied on the peripheral part of the wafer assembly by the abutment portion.

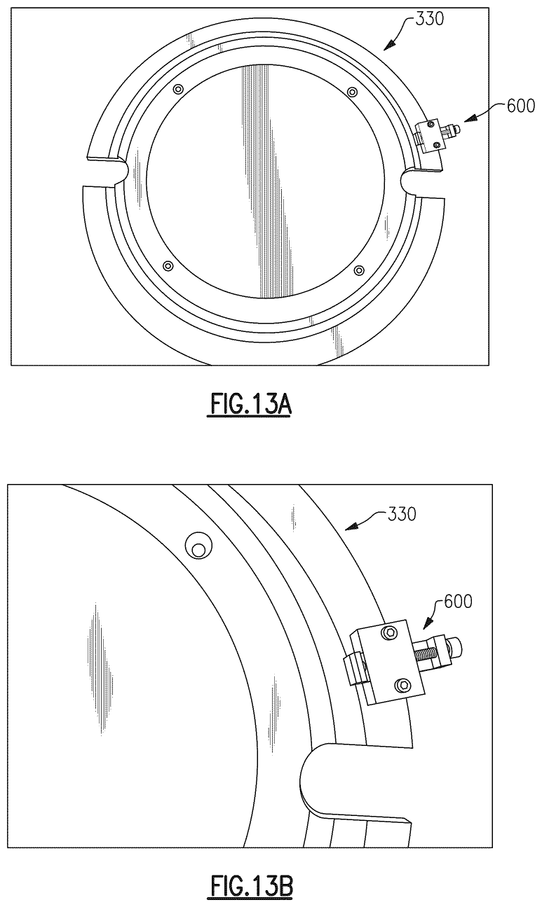

FIGS. 13A and 13B show the retainer attached to a chuck table 330. The chuck table is similar to that of FIG. 3 and like features have been given like reference numerals. The retainer 600 is attached to the periphery of the chuck table. In this example, only one retainer is attached to the chuck table. However, in other examples, more than one retainer is attached. Preferably, the chuck table has two or more retainers disposed about its periphery. Even more preferably, the retainers are disposed symmetrically about the periphery of the chuck table. In this way, the retainers work to hold the retainer on the chuck table in a balanced manner.

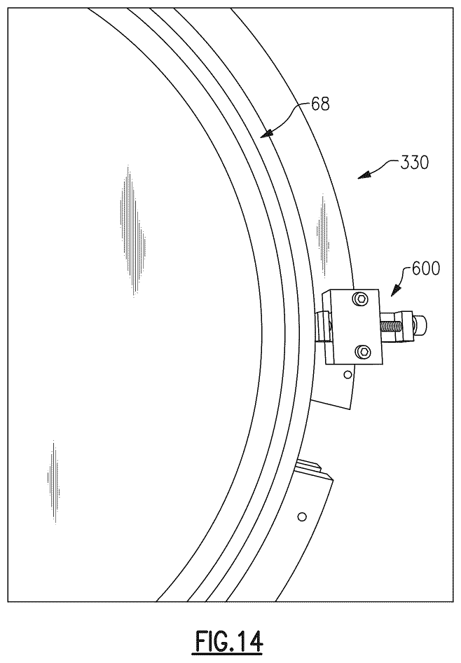

FIG. 14 shows the retainer 600 on the chuck table 330 holding part of a wafer assembly (not including the wafer) in place. The abutment portion pushes against a peripheral part of the wafer assembly 68. In this example, the peripheral part of the wafer assembly is a peripheral part of the ring. The peripheral part of the ring is, as a result, held against the supporting surface of the chuck table. More specifically, against the side of the raised portion of the chuck table. This retains the wafer assembly on the chuck table during the cleaning process.

In use, before the cleaning process is initiated, the wafer assembly is disposed on the chuck table having the retainers. More specifically, the wafer assembly is disposed on the supporting surface of the chuck table such that the ring encircles the raised portion of the supporting surface. To do this, an operator handling the wafer assembly uses the peripheral part of the wafer assembly, in this example the ring, against the first protrusion of the abutment portion. This slides the abutment portion relative to the attachment portion of the retainer in a direction moving away from the center of the chuck table. This compresses the spring of the biasing portion of the retainer. Once the wafer assembly is in place, as described above, the abutment portion of the retainer will push the ring of the wafer assembly against the supporting surface of the chuck table, holding it in place. The operator can then initiate the cleaning cycle. The skilled person will understand that a retainer as described herein is also suitable for holding a wafer assembly on a chuck table for different wafer processing procedures. This is enabled by the retrofittable design of the retainer, as described below.

A retainer as described above has several advantages. By securing the wafer assembly to the chuck table, the chuck table is less likely to become dislodged from the chuck table during the cleaning process. This prevents the wafer from becoming damaged. Furthermore, with the retainer being attachable to a chuck table by screws, the retainer is retrofittable onto existing chuck tables. This enables existing chuck tables to be relatively simply upgraded. This is particularly advantageous when the vacuum mechanism for holding the wafer assembly in place on known chuck tables, as described above, fails. A retainer as described herein can be retrofitted to such a faulty chuck table relatively quickly in comparison to fixing the vacuum system itself. The adjustment element is also particularly advantageous, enabling the retainer to be adjusted for use with different wafer assembly configurations. For example, the proximity of the abutment portion to the supporting surface can be adjusted accordingly for wafers with thicker or thinner rings to ensure the abutment portion effectively pushes against the ring to hold it in place. A further advantage lies in the way the wafer assembly is held in place. The abutment portion pushes against the peripheral edge of the ring in a radial direction towards the center of the chuck table. In other words, the contact is on the side of the ring. The abutment portion slides back and forth along this direction for removal and placement of the wafer assembly. This allows for easy removal and replacement of the wafer assembly when compared to a mechanism that holds the wafer assembly top down.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A retainer for retaining a wafer assembly on a chuck table supporting the wafer assembly during a cleaning process, the retainer comprising:
an attachment portion configured to attach the retainer to the chuck table;
an abutment portion configured to abut a peripheral part of the wafer assembly, the abutment portion being slidably fixed to the attachment portion; and
a biaser configured to bias the abutment portion towards the peripheral part of the wafer assembly such that the abutment portion pushes the peripheral part against a supporting surface of the chuck table so as to retain the wafer assembly on the chuck table.

2. A retainer according to claim 1 wherein the biaser has a spring.

3. A retainer according to claim 2 wherein the biaser further has a central core configured to engage the abutment portion.

4. A retainer according to claim 1 further comprising an adjustment element configured to adjust a pressure applied by the abutment portion to the peripheral part of the wafer assembly.

5. A retainer according to claim 4 wherein the adjustment element has a screw mechanism configured to adjust the pressure applied by the abutment portion by increasing or decreasing a distance between the abutment portion in a rest position and the peripheral part of the wafer assembly.

6. A retainer according to claim 5 wherein decreasing the distance between the abutment portion in the rest position and the peripheral part of the wafer assembly increases the pressure applied by the abutment portion.

7. A retainer according to claim 5 wherein increasing the distance between the abutment portion in the rest position and the peripheral part of the wafer assembly decreases the pressure applied by the abutment portion.

8. A retainer according to claim 1 wherein sliding the abutment portion relative to the attachment portion causes the biaser to exert a biasing force on the abutment portion in an opposite direction.

9. A retainer according to claim 1 wherein the attachment portion has screws configured to attach the attachment portion to the chuck table.

10. A chuck table for supporting a wafer assembly during a cleaning process, the chuck table comprising:
a supporting surface configured to support a wafer assembly; and
a retainer configured to retain the wafer assembly on the chuck table, the retainer having:
an attachment portion configured to attach the retainer to the chuck table;
an abutment portion configured to abut a peripheral part of the wafer assembly, the abutment portion being slidably fixed to the attachment portion; and
a biaser configured to bias the abutment portion towards the peripheral part of the wafer assembly such that the abutment portion pushes the peripheral part against the supporting surface of the chuck table so as to retain the wafer assembly on the chuck table.

11. A chuck table according to claim 10 wherein the attachment portion is attached to a peripheral portion of the chuck table.

12. A chuck table according to claim 10 further comprising a plurality of said retainers symmetrically disposed about a periphery of the chuck table.

13. A chuck table according to claim 10 further comprising the wafer assembly including a wafer.

14. A chuck table according to claim 13 wherein the wafer assembly further includes a portion of tape, the wafer being disposed on the portion of tape.

15. A chuck table according to claim 13 wherein the wafer assembly further has a ring disposed about its periphery, the peripheral part of the wafer assembly being part of the ring.

16. A chuck table according to claim 13 wherein the supporting surface of the chuck table includes a raised portion with a profile that is complementary to the profile of the wafer assembly such that the abutment portion is configured to push the peripheral part of the wafer assembly against a complementary peripheral part of the raised portion.

17. A method for cleaning a wafer assembly, the method comprising:
disposing a wafer assembly having a wafer on a supporting surface of a chuck table;
abutting a peripheral part of the wafer assembly against an abutment portion of a retainer attached to the chuck table by way of an attachment portion so as to slide the abutment portion relative to the attachment portion such that the abutment portion is biased towards the peripheral part of the wafer assembly, thereby pushing the peripheral part of the wafer assembly against the supporting portion of the chuck table so as to retain the wafer assembly on the chuck table.

18. The method of claim 17 further comprising initiating a cleaning cycle.

19. The method of claim 17 further comprising adjusting a pressure applied by the abutment portion to the peripheral part of the wafer assembly.

20. The method of claim 17 wherein adjusting the pressure applied by the abutment portion includes increasing or decreasing a distance between the abutment portion in a rest position and the peripheral part of the wafer assembly.
